(19) United States
(12) Patent Application Publication
(10) Pub. No.: US 2026/0081564 A1
(43) Pub. Date: Mar. 19, 2026

(54) AMPLIFIER CIRCUIT FOR BROADBAND AND LOW-NOISE AMPLIFICATION OF A CAPACITIVE CURRENT SOURCE AND A SENSOR SYSTEM

(71) Applicant: WIREDSENSE GMBH, Hamburg (DE)

(72) Inventors: Matthias BUDDEN, Hamburg (DE); Thomas GEBERT, Elmshorn (DE)

(21) Appl. No.: 19/107,852

(22) PCT Filed: Sep. 1, 2023
(86) PCT No.: PCT/EP2023/074074

§ 371 Date: Feb. 28, 2025

(30) Foreign Application Priority Data
Sep. 2, 2022 (DE) 10 2022 122 333.7

(51) Int. Cl. H03F 1/08; H03F 1/26; H03F 3/50; H05K 1/02

(52) U.S. Cl. CPC H03F 1/086; H03F 1/26; H03F 3/50; H05K 1/0216; H03F 2200/144; H03F 2200/294

(57) ABSTRACT

The invention relates to an amplifier circuit (1) for broadband and low-noise amplification of a capacitive current source, preferably of a pyroelectric sensor, comprising a signal input (3), which can be connected to the capacitive current source in a node K₁; an input stage (A1), wherein the input stage (A1) is connected to the node K₁ at an input (7) of the input stage (A1) and has a node K₂ at the output (9) of the input stage (A1), wherein the input stage (A1) is configured to amplify an input voltage at least 3-fold, wherein the input stage (A1) is configured to provide a high-ohm input resistance at the input of the input stage (A1), wherein the input stage (A1) is configured to provide a stable and load-independent voltage at the output of the input stage (A1); an amplifier cascade, wherein the amplifier cascade (11) has at least one first and one second amplifier (A2, A3), each with an input (13, 17) and an output (15, 19), wherein the output (19) of the first amplifier (A2) is connected to the input (17) of the second amplifier (A3) in a node K₃, wherein the input (13) of the first amplifier (A2) is connected to the node K₂, wherein the output (19) of the second amplifier (A3) is connected to a node K₄, wherein the amplifier cascade (11) is configured to generate a high signal amplification with a low phase rotation over a wide frequency range; a feedback network (F1), wherein the feedback network (F1) is connected to the input (7) of the input stage (A1) in the node K₁ and the output (19) of the second amplifier (A3) in the node K₄, wherein the feedback network (F1) is configured to provide a high-ohm feedback resistor with a parasitic capacitance of less than 0.5 pF, wherein the feedback network (F1) is configured to provide a negative feedback to an assembly comprising the input stage (A1) and the amplifier cascade (11); and a signal output (21), which is connected to a node K₅, wherein the node K₅ is connected to the node K₄ or corresponds to the node K₄. The invention also relates to a sensor system.

The invention relates to an amplifier circuit for broadband and low-noise amplification of a capacitive current source, preferably of a pyroelectric sensor, and to a sensor system. The subject matter of the invention is defined in the appended patent claims.

Highly sensitive detection of electromagnetic radiation in the infrared and terahertz range is relevant for a variety of applications. For example, heat sensors are used both in motion detectors and fire alarms as well as for gas analysis and in spectrometers for chemical material analysis. For challenging measurements at room temperature, capacitive current sources, such as pyroelectric sensors, are very common due to their simple structure and the associated low costs. The core of a pyroelectric sensor is a crystal of a pyroelectric material. In these materials, the centers of charge of positive and negative ions do not coincide, as a result of which an electrical polarization forms, which can be aligned along a crystal axis. Even the smallest changes in temperature of the crystal, such as due to the impingement of thermal radiation, lead to a change in this polarization. An increase in temperature causes, on the one hand, a direct reduction in the spontaneous polarization; on the other hand, it also indirectly facilitates a change in the dipole orientation due to the expansion of the material. As a result, surface charges form, proportionally to the change in temperature, on the boundary surfaces of the crystal perpendicular to its polar axis. The charges can flow out through electrodes attached to these surfaces and can thus be measured as current.

Since the currents generated by a pyroelectric crystal are typically on the order of magnitude of several picoamperes, low-noise measurement electronics with an amplifier circuit with high amplification are required to evaluate them. If, at the same time, the largest possible frequency bandwidth should be achieved, this places high demands on the amplifier circuit used for this purpose. With a given sensor element, this amplifier circuit is responsible to a significant extent for the overall performance of the sensor system.

Circuits for measuring such small currents are known in the prior art.

The disadvantage of the amplifier circuits known in the prior art is a low bandwidth at high amplifications of the signal of the capacitive current source, for example, of a pyroelectric sensor. The amplified signals also often have a strong noise. In addition, the amplifier circuits known in the prior art are often strongly dependent on their input capacitance.

The object of the present invention is therefore to provide a transimpedance amplifier (TIA) or else an amplifier circuit that enables low-noise amplification of a signal of a capacitive current source, in particular of a pyroelectric sensor, with a high bandwidth and that eliminates the disadvantages of the prior art.

The object is achieved in a first aspect of the invention by the amplifier circuit according to the invention according to claim 1. The object is also achieved in a second aspect of the invention by the sensor system according to the invention according to claim 20. Preferred embodiments according to the invention are apparent from the dependent claims and the following explanations.

The object is achieved in the first aspect of the invention by the amplifier circuit for broadband and low-noise amplification of a capacitive current source, preferably of a pyroelectric sensor, according to the features of claim 1. The amplifier circuit for broadband and low-noise amplification of a capacitive current source, preferably of a pyroelectric sensor, according to claim 1 comprises a signal input, which can be connected to the capacitive current source in a node K₁; an input stage, wherein the input stage is connected at one input of the input stage to the node K₁ and has a node K₂ at the output of the input stage, wherein the input stage is configured to amplify an input voltage at least 3-fold, wherein the input stage is configured to provide a high-ohm input resistance at the input of the input stage, wherein the input stage is configured to provide a stable and load-independent voltage at the output of the input stage; an amplifier cascade, wherein the amplifier cascade has at least one first and one second amplifier, each with one input and one output, wherein the output of the first amplifier is connected in a node K₃ to the input of the second amplifier, wherein the input of the first amplifier is connected to the node K₂, wherein the output of the second amplifier is connected to a node K₄, wherein the amplifier cascade is configured to generate a high signal amplification with a low phase rotation over a wide frequency range; a feedback network, wherein the feedback network is connected to the input of the input stage in the node K₁ and the output of the second amplifier in the node K₄, wherein the feedback network is configured to provide a high-ohm feedback resistor with a parasitic capacitance of less than 0.5 pF, wherein the feedback network is configured to provide negative feedback to an assembly comprising the input stage and the amplifier cascade; and a signal output, which is connected to a node K₅, wherein the node K₅ is connected to the node K₄ or corresponds to the node K₄.

The amplifier circuit according to the invention is a circuit of a transimpedance amplifier (TIA). In the following, the terms amplifier circuit and transimpedance amplifier are used as synonyms.

In the context of the invention, a capacitive current source is a current source with an output impedance that can be described in good approximation by an electrical capacitance. This output impedance corresponds to the source impedance at the downstream TIA input. Examples of capacitive current sources can be photodiodes, CCD pixels, tunneling current sensors, pressure and tactile sensors, (Geiger-Müller) counters, photomultipliers (such as microchannel plates), acceleration sensors, or preferably a pyroelectric sensor. In the context of this invention, a pyroelectric sensor is a component in which, as a result of its pyroelectric properties, a temperature difference causes a change in the electrical voltage of the component.

The pyroelectric sensor can be described by an equivalent circuit diagram consisting of a parallel circuit of current source I_{py}, crystal capacitance C_{py}, and loss resistance R_{py}. The specific resistance of pyroelectric materials can be very high and is typically on the order of magnitude of multiple 10¹⁰ Ω cm. At usual crystal sizes of a few mm in diameter, the electrical capacitance of a sensor element can vary between 100 pF and 1 nF depending on the crystal thickness.

In the context of the invention, a pyroelectric sensor has a crystal with a pyroelectric material or is a crystal having or consisting of a pyroelectric material. The electrical capacitance C_{py} of a pyroelectric sensor is determined primarily by the thickness and area of the pyroelectric crystal. For broadband amplification of different sensor elements, a transimpedance amplifier is therefore required, which is, in particular, insensitive to changes in the source impedance.

The amplifier circuit according to the invention, i.e., the transimpedance amplifier, converts an incoming current signal into a proportional output voltage and can thus be considered as a current-controlled voltage source. This behavior is particularly advantageous when measuring and amplifying small current signals. This behavior is particularly suitable for measuring small currents of a pyroelectric sensor element. The current generated at the boundary surfaces of the pyroelectric material, which is also known as a pyroelectric, is thus converted into an easily measurable voltage. This voltage can then be read out, for example, by an analog-to-digital converter. The capacitive current source preferably has a current on the order of magnitude of a pyroelectric sensor.

In the context of the invention, a signal input describes a hardware interface of the amplifier circuit, to which the current signal of the capacitive current source can be applied. For this purpose, the signal input can be connected to the capacitive current source. To connect to the capacitive current source, the signal input can have, for example, one or more of the following connection devices: clamp connectors, crimp connectors, plug connectors, screw connectors, solder pads, solder points, high-frequency connectors.

It is also conceivable for the signal input of the amplifier circuit according to the invention to be connected directly to the capacitive current source. In this case, the amplifier circuit according to the invention can form a unit with the capacitive current source. For example, the amplifier circuit according to the invention can be integrated into the capacitive current source.

In the context of the invention, a connection to a node Kx, wherein x is a natural number, describes a direct or indirect electrical connection to the node Kx, preferably a direct electrical connection. Within the meaning of the invention, a node describes a connection point of at least two conductor paths of the amplifier circuit. A direct connection to the node Kx is an electrically conductive connection to the node Kx that comprises no further components or reroutings via further nodes. An indirect connection to the node Kx is an electrically conductive connection to the node Kx that comprises at least one electrical and/or electronic component or one or more component groups. Within the meaning of the invention, a component group is a group of components comprising at least two or more electrical and/or electronic components. Additionally or alternatively, the indirect connection can also comprise a rerouting via one or more further nodes.

Within the meaning of the invention, an input stage is a component or a component group that is arranged downstream of the signal input and is arranged upstream of a subsequent stage, for example the amplifier cascade. The input stage is designed and configured such that an input signal, i.e., a current signal of the capacitive sensor, which is applied to the signal input or else node K₁, is amplified. The amplification is at least 3-fold, preferably at least 5-fold, more preferably at least 10-fold. Additionally or alternatively, the amplification can be at most up to 25-fold, preferably at most 20-fold. An amplification in the range of 5-fold to 10-fold is particularly preferred. This range typically provides good amplification with optimally low noise. The signal output by the input stage at the output of the input stage can be inverted or non-inverted. The amplification preferably takes place as linear closed-loop control, preferably by using a linear amplifier. Alternatively, the amplification can also take place by utilizing an advantageous, non-linear characteristic curve of a corresponding amplifying component.

The input stage is configured to provide a high-ohm input resistance at the input of the input stage and, at the same time, provide a stable and load-independent voltage at the output of the input stage. The input stage is preferably very low-noise. Within the meaning of the invention, a low-noise input stage is an input stage with a spectral noise density of less than

$$5 \frac{nV}{\sqrt{Hz}} .$$

A low-noise input stage results from minimizing the voltage noise and current noise Vₙ and Iₙ, respectively, at the input of the input stage.

In order to achieve this, the input stage is preferably set up discretely, i.e., from at least two semiconductor components that are configured to control electrical voltages and/or currents in an open-loop manner. For example, the input stage can be made from transistors. The transistors can be either bipolar transistors or field-effect transistors or a combination of at least one bipolar transistor and at least one field-effect transistor.

Preferably, the discrete structure of the input stage comprises a component or a component group which provides an amplification of the input signal and a component or a component group which lowers or adapts the impedance of the output of the input stage. The input stage thereby provides a voltage at its output with a value that does not depend on the load by the subsequent circuit.

Preferably, the discrete structure comprises at least one low-pass, also called a low-pass filter, for suppressing noise of the supply voltage of the input stage.

Within the meaning of the invention, an amplifier cascade is a series connection or else a chain of at least two amplifiers, i.e., at least one first amplifier with a first amplification factor G_{Q3} and a second amplifier with a second amplification factor G_{Q4}, that amplify an input signal. The amplifier cascade is downstream of the input stage.

The amplifier cascade can have two, three, four, or more amplifiers. Preferably, the amplifier cascade comprises two amplifiers.

In the context of the invention, a high signal amplification by the amplifier cascade describes an intrinsic amplification of an input signal by at least the factor of 10⁴. Within the meaning of the invention, a low phase rotation of the entire amplifier cascade including the input stage describes a phase rotation of at most −160°. Within the meaning of the invention, a further frequency range describes a frequency bandwidth of at least 500 Hz, preferably at least 1 kHz, more preferably at least 10 kHz, particularly preferably at least 100 kHz. A high signal amplification by a factor of 10⁸ at a frequency bandwidth of 10 kHz is advantageous. A signal amplification by a factor of 10⁹ at a frequency bandwidth of 10 kHz or a signal amplification by a factor of 10⁸ at a frequency bandwidth of 100 kHz is particularly advantageous.

The amplification can take place in open-loop gain or closed-loop gain. The amplification preferably takes place in open-loop gain. Preferably, the first amplifier is a linear closed-loop controller, which controls the function of the amplifier circuit via the feedback network. Preferably, the second amplifier has a low amplification G_{Q4}. The amplification can be firmly defined or adjustable. In this case, the second amplifier can amplify the output signal of the first amplifier with a greater bandwidth and reduced phase rotation. Additionally, with a given negative feedback, it can provide a greater frequency range with a small input impedance.

The first and second amplifiers and, if applicable, further subsequent amplifiers can be designed to be either inverting, non-inverting, or as a combination of inverting and non-inverting amplifiers. Preferably, the first and second amplifiers are non-inverting.

Preferably, the first amplification factor G_{Q3} is much greater than the second amplification factor G_{Q4}:G_{Q3}>>G_{Q4}. For example, the ratio G_{Q3}/G_{Q4} can be at least 10³, preferably 10⁴, more preferably 10⁵.

Within the meaning of the invention, a feedback network describes a component group comprising at least one high-ohm feedback resistor R_{fb} for providing a negative feedback of the assembly consisting of the input stage and amplifier cascade. This resistor defines the transimpedance amplification as the ratio of output voltage to its input current. Within the meaning of the invention, a high-ohm feedback resistor has an ohmic resistance value of 10 GΩ at a transimpedance amplification of 10 GV/A.

For amplification of the very low currents from capacitive current sources, preferably from pyroelectric sensors, a very large signal amplification is required. In this case, the amplification factor should preferably exceed the factor of 10⁶. A signal amplification by a factor of 10⁹ at a frequency bandwidth of 10 kHz or a signal amplification by a factor of 10⁸ at a frequency bandwidth of 100 kHz is particularly advantageous. In other words, the amplifier circuit according to the invention can have a TIA amplification bandwidth product of more than 10 TV/AHz.

Only the true transimpedance portion of the amplifier circuit according to the invention is relevant for the noise characteristics of the amplifier circuit according to the invention. Downstream voltage amplifiers, even a voltage filter circuit, can no longer improve the noise. With a downstream voltage amplifier or else voltage filter circuit, only the noise bandwidth can be changed, but not the noise density, which is important for the quality of the amplified signal.

In order to obtain an optimal signal-to-noise ratio of the amplified signal, it is important for the input current noise of the amplifier circuit to be as low as possible when a high amplification by the amplifier circuit according to the invention is specified. In this case, the input current including the input current noise is converted into a voltage by the amplifier circuit according to the invention. In the process, the input current noise is significantly influenced by the selected feedback, i.e., by the Johnson-Nyquist noise of the feedback resistor. Preferably, at room temperature and an amplification of 500 MV/A, the input current noise is approximately

$$10 \frac{fA}{\sqrt{Hz}} ,$$

more preferably

$$5.8 \frac{fA}{\sqrt{Hz}} .$$

More preferably, at room temperature and an amplification of 5 GV/A, the input current noise is approximately

$$4 \frac{fA}{\sqrt{Hz}} ,$$

particularly preferably approximately

$$1.8 \frac{fA}{\sqrt{Hz}} .$$

Preferably, the amplifier circuit according to the invention is a linear amplifier circuit. This is realized by the negative feedback of the input stage and the amplifier cascade with the linear feedback network. For this reason, the feedback network is connected to the nodes K₁ and K₄.

Preferably, the feedback network has a compensation circuit, which is configured to compensate for a potentially present undesired parasitic capacitance of the high-ohm feedback resistor. In other words, the compensation circuit is configured to minimize, preferably to remove, a frequency dependency of the feedback network. For example, the compensation circuit can have at least one capacitor, which advantageously interacts with the high-ohm feedback resistor. Additionally or alternatively, the compensation circuit can comprise a bandpass, for example, a high-pass and/or low-pass.

Preferably, the compensation circuit has electronic or electrical components, the ohmic resistance or the capacitance of which can be variably adjusted. This enables an exact coordination of the compensation circuit to the parasitic capacitance of the ohmic resistor, such that the parasitic capacitance is compensated for and the frequency dependency of the feedback network (nearly) disappears.

In the context of the invention, a signal output describes a hardware interface of the amplifier circuit, at which the output signal which is amplified in a broadband and low-noise manner can be output. The signal output can be connected to external devices for further processing and use of the output signal. For example, the signal output can be connected to an analog-to-digital converter and a subsequent measurement and analysis apparatus, such as a measurement computer. To connect to external devices, the signal output can have, for example, one or more of the following connection devices: clamp connectors, crimp connectors, plug connectors, screw connectors, solder pads, solder points, high-frequency connectors.

The amplifier circuit according to the invention has the surprising advantage that an extremely low-noise and simultaneously very high amplification is possible at a high frequency bandwidth. As a result, the amplifier circuit according to the invention delivers an optimal signal-to-noise ratio. For example, the amplifier circuit according to the invention makes possible amplifications G of, for example, G≈10⁹ V/A and bandwidths of greater than 10 kHz, in particular up to 100 kHz, which at this amplification is considerably faster than is typical for amplifier circuits that have previously been commercially available. The amplifier circuit is robust against an increase in the input capacitance at the signal input. This allows thinner and therefore more sensitive pyroelectric sensor elements to be used even at high amplifications.

In a preferred embodiment according to a first aspect of the invention, the input stage has a junction field-effect transistor and a bipolar transistor, wherein a drain connection of the junction field-effect transistor is connected to a base connection of the bipolar transistor, wherein the junction field-effect transistor is wired as a source circuit, wherein the bipolar transistor is wired as an emitter follower, wherein the first and second amplifiers of the amplifier cascade are an operational amplifier, wherein the first operational amplifier has a voltage amplification of more than 10⁴, wherein the second operational amplifier has a voltage amplification of at most 10³, wherein the feedback network has a high-ohm feedback resistor with a parallel capacitor, wherein the feedback network has a low-pass connected in series.

Junction field-effect transistors are known in the prior art. Junction field-effect transistors typically have three connections: source, gate, and drain. Bipolar transistors are known in the prior art. Bipolar transistors typically have three connections: collector, base, emitter.

Preferably, the gate connection of the junction field-effect transistor is connected to the node K₁. Preferably, the emitter connection of the bipolar transistor is connected to the node K₂.

The source circuit of junction field-effect transistors and the emitter follower circuit of bipolar transistors are sufficiently known in the prior art.

The source circuit is configured to invertingly amplify the input signal at the junction field-effect transistor by at least the factor 3, preferably by the factor 5 to 20. However, it is also conceivable for the input signal to be amplified in a non-inverting manner.

The emitter follower is configured to reduce the output impedance of the input stage without additional voltage amplification. This allows a stable voltage transfer at the node K₂, the value of which does not depend on the load by the following circuit. The emitter follower compensates for an offset potential at the drain output of the field-effect transistor with a fixed voltage drop between the base and emitter of the bipolar transistor. Due to this offset correction, the two operational amplifiers in the amplifier cascade following the input stage must counter-control less strongly in order to control their input signal in a closed-loop manner to zero. In a real operational amplifier, the common-mode input voltage should be close to zero. Without compensation, the shift of the signal level due to the field-effect transistor would lead the following highly amplifying amplifier cascade to saturation or else limit the dynamic range of the amplification.

Preferably, the drain connection of the junction field-effect transistor and/or the collector connection and emitter connection of the bipolar transistor each have a resistor or a series connection of at least two resistors. The optimal operating point of the input stage can be set via suitable resistors or series connections of resistors at the drain connection of the junction field-effect transistor and/or at the collector connection and emitter connection of the bipolar transistor. An optimal operating point of the input stage is given at a maximally large amplification at a high bandwidth and low noise of the output signal.

Preferably, at least the series connection of resistors at the drain connection of the junction field-effect transistor and/or at the collector connection and emitter connection of the bipolar transistor has a parallel low-pass. The low-pass can advantageously suppress noise of the supply voltage. More preferably, each series connection of resistors at the drain connection of the junction field-effect transistor and at the collector connection and emitter connection of the bipolar transistor has a parallel low-pass.

Preferably, the first operational amplifier has a voltage amplification G_{Q3} of more than 10⁶, even more preferably more than 10⁷.

Preferably, the second operational amplifier has a voltage amplification G_{Q4} of at most 1000, more preferably at most 400, even more preferably at most 250.

The capacitor C₅ in parallel connection to the high-ohm feedback resistor and the low-pass connected in series therewith, for example consisting of an ohmic resistor R₈ and a capacitor C₆, form a possible embodiment of the compensation circuit mentioned above. The compensation circuit is configured to reduce an unavoidable parasitic capacitance of the high-ohm feedback resistor to zero or nearly zero. Nearly zero describes, in this case, a parasitic capacitance of less than 0.5 pF, preferably less than 0.1 pF.

Preferably, the low-pass is connected to the node K₄. Preferably, the parallel connection consisting of high-ohm feedback resistor R₇ and capacitor C₅ is connected at least to the node K₁.

The parasitic capacitance of the high-ohm feedback resistor R₇ generates a pole in the control loop, which can be compensated for by the low-pass consisting of R₈ and C₆. This can be shown by decomposition of the compensation network into its two components: The transfer function of a, for example, inverting transimpedance amplifier with the feedback Z_{f} consisting of R₇ and C₅ alone is:

$${V}_{{K}_{f}} = - {I}_{i n} \times {Z}_{f} ⇔ \frac{{V}_{{K}_{f}}}{{I}_{i n}} = - \frac{{R}_{7}}{1 + j ω {R}_{7} {C}_{5}}$$

V_{K}_{_{f}} is in this case the voltage at the node K_{f}. The directly upstream low-pass consisting of R₈ and C₆ alone has the following transfer function:

$$\frac{{V}_{{K}_{f}}}{{V}_{{K}_{4}}} = \frac{1}{1 + j ω {R}_{8} {C}_{6}}$$

with the potential V_{K}_{₄} at the node K₄. Substituting results in the entire transfer function of the compensation circuit:

$$\frac{{V}_{{K}_{4}}}{{I}_{i n}} = - {R}_{7} \frac{1 + j ω {R}_{8} {C}_{6}}{1 + j ω {R}_{7} {C}_{5}}$$

This makes it immediately clear that the transfer function loses its frequency dependency when R₈C₆=R₇C₅. Therefore, a parasitic capacitance of the high-ohm feedback resistor R₈ can be compensated for by suitably adjusting the low-pass filter.

Preferably, the high-ohm feedback resistor R₈ is a combination of a fixed resistor and a potentiometer.

The amplifier circuit according to the invention has the advantage that it is made from easily accessible, cost-effective, and reliable electronic components.

The special arrangement of the various component groups, in particular the nesting of the input stage, amplifier cascade, and feedback network, also achieves a performance that has not yet been achieved in the prior art, consisting of broadband and low-noise high amplification of the signal of the capacitive current source, preferably of the pyroelectric sensor.

Junction field-effect transistors have very low input current noise. As a result, the noise of the signal at the signal output of the amplifier circuit according to the invention is kept low and the signal-to-noise ratio is improved.

This embodiment thus offers, in particular, a very cost-effective amplifier circuit with the advantages already mentioned above of broadband and low-noise high amplification.

In a preferred embodiment according to the first aspect of the invention, the amplifier circuit additionally has an output stage, wherein the output stage is connected to the node K₄ at an input of the output stage and is connected to the signal output in the node K₅ at an output of the output stage, wherein the output stage is configured to amplify a voltage at the input of the output stage by up to 20-fold, wherein the output stage is configured to filter DC voltage disturbances at the input of the output stage and to adapt a signal level at the output of the output stage to K₅.

Within the meaning of the invention, an output stage is a component group downstream of the amplifier cascade that is configured to amplify a voltage at the input of the output stage, filter DC voltage disturbances at the input of the output stage, and adapt a signal level of the voltage at the output of the output stage.

Preferably, the amplification of the voltage at the input of the output stage is at most 15-fold, more preferably at most 10-fold. The amplification can be an inverting or non-inverting amplification. The amplification can take place, for example, by means of one or more of the following amplifying components: field-effect transistors, unipolar transistors, bipolar transistors, operational amplifiers.

Capacitive current sources, preferably pyroelectric sensors, typically measure changes in temperature. The voltage signal derived (and amplified) from the current signal of the capacitive current source is thus also a temporally variable signal. DC voltage portions in the voltage signal, such as from a non-optimal offset correction of the input stage, therefore provide no information about the measurement and are therefore unwanted. The filtering of DC voltage disturbances at the input of the output stage thus considerably improves the signal quality.

The filtering of DC voltage disturbances can take place, for example, with a frequency-dependent circuit, such as a bandpass, or with at least one frequency-dependent component, such as a capacitor. The frequency-dependent circuit or the at least one frequency-dependent component is preferably downstream of the input of the output stage and preferably upstream of the amplifying component.

The signal level can be adapted, for example, with the solutions known in the prior art. For example, an amplifier circuit based on an operational amplifier can be used.

The output stage and a subsequent amplification that may be associated with it has the advantage that the signal level can be optimally adapted to the dynamic range of the typically following evaluation electronics (such as an analog-to-digital converter). In addition, due to the additional increase of the signal level, any artifacts become less relevant relative to the signal.

This therefore results in an optimal signal-to-noise ratio in the following measurement electronics.

In a preferred embodiment according to the first aspect of the invention, the output stage comprises an inverting bandpass amplifier, wherein an input of the bandpass amplifier is AC-coupled.

Preferably, the input of the amplifier of the output stage is connected to the node K₄ via a capacitor connected in series. Preferably, the output of the amplifier of the output stage is connected to the node K₅ and the signal output. Alternatively, the bandpass amplifier can also be designed to be non-inverting.

The output stage can be made of easily available, cost-effective, and reliable electronic components. This embodiment thus offers, in particular, a very cost-effective amplifier circuit with the advantages already mentioned above of broadband and low-noise high amplification.

In a preferred embodiment according to the first aspect of the invention, the amplifier circuit additionally comprises an amplitude limiter, wherein the amplitude limiter is connected to the node K₄ or K₅ at an input of the amplitude limiter and is connected to the node K₃ at an output of the amplitude limiter, wherein the amplitude limiter is configured to limit the amplitude of the output signal at the signal output when a threshold is exceeded at the node K₄ or node K₅.

Within the meaning of the invention, an amplitude limiter is a component group that is configured to limit the amplitude of the output signal at the signal output when a threshold is exceeded.

The limitation of the amplitude is achieved using a non-linear transfer function. A non-linear limitation of the amplitude can take place, for example, with the aid of Zener diodes (Z-diodes). Alternatively, other components with a non-linear transfer function can also be used.

This non-linear feedback increases the stability of the circuit. Especially in the case of the amplification of the signal of a pyroelectric sensor, too much light can easily be applied to the sensor, which would cause the amplifier stage to saturate. This prevents overloading at the signal output of the amplifier circuit according to the invention.

In particular in the interaction with the output stage, the following synergies result: The non-linear negative feedback is performed at node K₃ instead of node K₁ in order to reduce or else prevent an increase in the noise of the output signal at the signal output at the node K₅ due to a possible capacitance of at least one component in the amplitude limiter. In order for negative feedback to be applied at node K₃ in a controlled manner, the polarity of the amplification along a closed loop of the feedback must be inverting (negative) overall. For this purpose, the output stage is preferably designed to be inverting and the amplitude limiter is arranged along the connection between the nodes K₅ and K₃.

Another reason for arranging the amplitude limiter after the first amplifier in the amplifier cascade is that the amplifiers in the amplifier cascade respond very sensitively to additional capacitances and a reduced input impedance. Non-linear components in particular, such as diodes, would add strong noise.

Finally, oscillation of the amplifier cascade or else overloading of the amplifier cascade can be reduced or completely prevented by the interaction of the amplitude limiter with the output stage.

In a preferred embodiment according to the first aspect of the invention, the amplitude limiter has two Z-diodes that are connected in series with opposing polarity.

Z-diodes are known in the prior art. Z-diodes have a cathode and an anode. When the two Z-diodes are connected in series with opposing polarity, either the cathode in each case (or the anode in each case) of a Z-diode are preferably connected to the node K₃ and the signal output in the node K₅. Both anodes (or both cathodes) of the two Z-diodes are connected to each other. Negative feedback sets in when the voltage at K₅ exceeds a threshold. This threshold is dependent on the breakdown voltage of the Z-diode that is connected to K₅. The threshold can be adjusted by selecting the Z-diodes accordingly.

Preferably, the anodes of the Z-diodes are connected to ground via a series connection of an ohmic resistor and a capacitor.

Z-diodes are simple, reliable, and cost-effective components. They are therefore particularly well suited for amplitude limiting. In addition, in this context, the same advantages apply to amplitude limiting as were already explained in the previous paragraphs. To avoid unnecessary redundancy, reference is made here to the statements made above and they will not be repeated here.

In a preferred embodiment according to the first aspect of the invention, the amplifier circuit has a frequency response compensator, wherein the frequency response compensator is connected to the node K₃ and the node K₁, wherein the frequency response compensator is configured to decrease a vibration tendency of the amplifier cascade.

Within the meaning of the invention, a frequency response compensator is a component or a component group that decreases an unwanted vibration tendency of the entire amplifier circuit. In the context of the invention, a vibration tendency of the amplifier circuit describes a tendency of the amplifier circuit to oscillate in an unwanted manner.

For example, the frequency response compensator can have frequency-dependent components or frequency-dependent component groups. The frequency response compensator can have, for example, at least one or more of the following frequency-dependent components or frequency-dependent component groups: a capacitor connected in series, a capacitor connected in parallel, a bandpass, for example, a high-pass and/or a low-pass.

The frequency-dependent components or frequency-dependent component groups serve to stabilize the amplifier cascade through internal frequency compensation. When the phase of the signal rotates by 180° when the amplifier circuit according to the invention goes through a feedback loop (loop gain nearly −1), the negative feedback can become positive feedback and the amplifier cascade can have a tendency to vibrate. This behavior can be compensated for by the frequency-dependent components or frequency-dependent component groups. The frequency-dependent components or frequency-dependent component groups are preferably dimensioned such that the circuit stability of the amplifier cascade and of the entire amplifier circuit according to the invention is ensured, but at the same time the bandwidth is not limited too strongly.

With the aid of the frequency response compensator, an increase in the stability of the amplifier circuit according to the invention at high frequencies is thus possible. This reduces or avoids vibration of the amplifier circuit and improves the performance of the amplifier circuit. In particular, a flat transfer, i.e., a linear transfer function, can be realized at high frequencies and high amplifications due to the frequency response compensator. The ripple of the transfer function is reduced, preferably to less than 5%, particularly preferably to less than 3% of the maximum amplitude. This is necessary, in particular, in order to allow quantitative statements about the signal amplitude to be made in the case of broadband measurements.

In a preferred embodiment according to the first aspect of the invention, the frequency response compensator has a negative feedback via a capacitor.

The negative feedback capacitor is preferably connected to the nodes K₁ and K₃.

The negative feedback capacitor serves to stabilize the entire amplifier circuit through internal frequency compensation. When the phase of the signal rotates by 180° when the amplifier circuit according to the invention goes through a feedback loop (loop gain nearly −1), the negative feedback can become positive feedback and the amplifier circuit can have a tendency to vibrate. This behavior can be compensated for by the negative feedback capacitor. The capacitance value of the capacitor is preferably dimensioned such that the circuit stability of the amplifier cascade and of the entire amplifier circuit according to the invention is ensured, but at the same time the bandwidth is not limited too strongly.

Capacitors are simple, reliable, and cost-effective components. Implementing the frequency response compensation with a negative feedback capacitor is thus a simple and cost-effective implementation.

In addition, in this context, the same advantages apply to frequency response compensation as were already explained in the previous paragraphs. To avoid unnecessary redundancy, reference is made here to the statements made above and they will not be repeated here.

In a preferred embodiment according to the first aspect of the invention, the input stage has a component with a negative capacitance.

Within the meaning of the invention, a component with a negative capacitance is a component in which a reduction of the applied voltage results in an increase in the charge of the component. For this purpose, the component can have a material that has a negative capacitance. Initial experimental indications of such materials are given, for example, by M. Hoffmann, S. Slesazeck, and T. Mikolajick, “Progress and future prospects of negative capacitance electronics: A materials perspective,” APL Mater. 9, 020902 (2021) and A. K. Yadav, K. X. Nguyen, Z. Hong, et al. “Spatially resolved steady-state negative capacitance,” Nature 565, 468 (2019).

Examples of materials in which a negative capacitance can form are ferroelectric materials such as HfO₂ and lead zirconate titanate, or else heterostructures consisting of these ferroelectric and dielectric materials such as strontium titanate.

Preferably, the component with negative capacitance is combined with the signal input or the input stage such that the negative capacitance of the component compensates for the normal, positive, capacitance of the capacitive current source, preferably of the pyroelectric sensor. Alternatively or additionally, the component with negative capacitance can also be comprised in the feedback network and compensate there for the parasitic capacitance of the high-ohm feedback resistor.

The use of such a component reduces the noise considerably and thus improves the signal-to-noise ratio when measuring the signal of the capacitive current source, preferably of the pyroelectric sensor.

In a preferred embodiment according to the first aspect of the invention, the amplifier circuit or at least a part of the amplifier circuit is mounted on a circuit board, wherein at least one electronic component of the amplifier circuit is soldered to the circuit board with solder pads on the circuit board, wherein a region of the circuit board below the at least one electronic component outside of the solder pads is removed.

Within the meaning of the invention, a circuit board is any base that is suitable for permanently mechanically attaching and electrically connecting the amplifier circuit according to the invention or parts of the amplifier circuit according to the invention. Examples of circuit boards are flexible or rigid circuit boards. Circuit boards can have, for example, fiber-reinforced plastic or synthetic resin bonded paper as well as metal coatings and/or traces.

Within the meaning of the invention, solder pads describe regions on a circuit board that are typically coated with metal coatings and are suitable for a soldered connection by means of solder, for example, for bonding an electronic component.

In the context of the invention, removal of a region of the circuit board describes a region of the circuit board within which the material of the circuit board has been partially or completely removed. In other words, in this removed region, there is no circuit board material (complete removal) or less circuit board material (partial removal). The circuit board material can be removed, for example, by machining processes such as milling, drilling, or sawing. Alternatively, corresponding recesses without circuit board material can also be provided during manufacturing of the circuit board material.

Each structural element, such as an ohmic resistor, has a parasitic capacitance, which forms between the connections of the component and between the component and the environment. In particular with an ohmic resistor, the parasitic capacitance increases with the dimensions of the component. In particular, the high-ohm feedback resistor and the transistors of the input stage respond sensitively to changes in ambient conditions. Even the smallest deviations in the surrounding material of the circuit board, a protective varnish applied to the components and the circuit board, or flux residues from the soldering process can generate leakage currents on the order of magnitude of the current of the negative feedback circuits of the amplifier circuit according to the invention, which can influence the performance of the amplifier electronics according to the invention in a significantly disadvantageous manner. In particular, these effects are responsible for undesirably large fluctuations in quality within a production batch during manufacturing, which require reworking or generate waste and thus increase costs.

Preferably, the circuit board is removed centrally below a component such that only the region of the solder pad is present. A component connected to the solder pads can span the gap created in the circuit board by the removed region when the connections of the component are firmly soldered on, like a type of bridge. In this case, any soiling below the component is no longer possible.

This considerably increases the reproducibility of the performance of the amplifier circuit according to the invention during production. This also allows costs for any subsequent improvements of the performance of the amplifier circuit after production to be lowered or saved.

In a preferred embodiment according to the first aspect of the invention, the at least one electronic component is an electronic component or multiple components of the feedback network or is the entire feedback network.

The feedback network is particularly important for the function of the amplifier circuit according to the invention and, at the same time, is very sensitive to parasitic capacitances. The reduction of parasitic capacitances by removing the circuit board material thus leads to a considerable improvement in the performance of the amplifier circuit according to the invention.

In a preferred embodiment according to the first aspect of the invention, the at least one electronic component is an electronic component or multiple components of the input stage, preferably the field-effect transistor and/or the bipolar transistor.

The input stage is particularly important for the function of the amplifier circuit according to the invention and, at the same time, is very sensitive to parasitic capacitances. The reduction of parasitic capacitances by removing the circuit board material thus leads to a considerable improvement in the performance of the amplifier circuit according to the invention.

The amplifier circuit according to the invention according to one of claims 1 to 19 can preferably be used for measuring a current signal of a capacitive current source, preferably of a pyroelectric sensor.

The amplifier circuit according to the invention according to one of claims 1 to 19 can preferably be used for measuring a current signal of a capacitive current source, preferably of a pyroelectric sensor, in an infrared spectrometer, preferably an FTIR spectrometer (Fourier-transform infrared spectrometer).

The FTIR spectrometer (Fourier-transform infrared spectrometer) comprises the following components: an infrared radiation source, an interferometer with at least one arm that is variable in length, a reference laser, a measuring cell with a sample interface, preferably an ATR (attenuated total reflection) crystal which can be brought into contact with a sample, an infrared detector, a control system which is configured to change the length of the at least one arm of the interferometer, and a mirror arrangement outside the interferometer with at least two mirrors, each with a reflecting surface and a main body that comprises the reflecting surface, wherein the mirror arrangement is at least configured to direct a light beam from the interferometer onto the sample interface and to direct the light beam from the sample interface onto the infrared detector, wherein the main body of at least one mirror or of all mirrors of the mirror arrangement is/are made of a plastic material and/or of 3D printed metal, or the main body of at least one mirror or of all mirrors has/have plastic material and/or 3D printed metal.

With the help of the ATR crystal, an evanescent wave can be coupled into the sample material that is in contact with the ATR crystal or else the sample. This effect is also termed the optical tunnel effect. The remaining light carries information about the interaction with the sample, is guided out of the ATR crystal by means of total internal reflection, and can then be guided to an infrared detector, for example by reflection.

The combination of all the aforementioned preferred embodiments is, in turn, a preferred embodiment and describes a four-stage amplifier circuit, i.e., an amplifier circuit comprising four amplifier stages, with three feedback loops.

The first amplifier stage is formed by the input stage. The second and third amplifier stages are formed by the first and second amplifiers of the amplifier cascade. The fourth amplifier stage is formed by the output stage.

The first feedback loop is formed by the feedback network. The second feedback loop is formed by the amplitude limiter. The third feedback loop is formed by the internal frequency compensation.

Preferably, the input stage and the output stage are each an inverting amplifier stage. Preferably, the first and second amplifiers of the amplifier cascade are each or each form a non-inverting amplifier stage. The interplay of inverting and non-inverting amplifier stages enables separate feedback loops, each of which include only the first or last inverting stage and otherwise contain only non-inverting stages. The condition for negative feedback, an uneven number of inverting amplifier stages, is thus met for all feedback loops. The first feedback loop contains a linear component network for high amplifications with capacitance compensation. The second feedback loop generates the non-linear amplitude limitation. The third feedback loop is used for frequency response compensation of the entire circuit.

In a preferred embodiment according to the first aspect of the invention, the amplifier circuit additionally comprises a decoupler, wherein the decoupler is connected to the node K₄ and the input of the output stage, wherein the decoupler is configured to decouple an output of the amplifier cascade from the output stage.

In a preferred embodiment according to the first aspect of the invention, the decoupler has an impedance converter, preferably a non-inverting impedance converter or a combination of two inverting impedance converters, or wherein the decoupler is an impedance converter, preferably a non-inverting impedance converter or a combination of two inverting impedance converters. Particularly preferably, the decoupler is a non-inverting impedance converter or has a non-inverting impedance converter.

Impedance converters are technically simple, cost-effective, and reliable components or else component groups, with which the desired decoupling can be achieved. Non-inverting impedance converters have the advantage that they typically have a very high-ohm input, which is particularly advantageous for this circuit.

In a preferred embodiment according to the first aspect of the invention, the impedance converter has at least one or more of the following components or is one of the following components: MOSFET, bipolar transistor, operational amplifier, operational amplifier with high input resistance and low inherent noise, operational amplifier with high input resistance and low inherent noise, wherein the output of the operational amplifier is directly or indirectly fed back to its inverting input.

In a particularly preferred embodiment according to the first aspect of the invention, the impedance converter has at least one operational amplifier with high input resistance and low inherent noise, wherein the output of the operational amplifier is directly fed back to the inverting input.

In the context of the invention, a decoupling of the output of the amplifier cascade from the input of the output stage by the decoupler describes, in particular, a decoupling of the frequency dependency of the output stage from the upstream amplifier cascade. This frequency decoupling can be complete or only partial. In the case of a complete frequency decoupling, the ideal frequency dependency of the output stage is not distorted and the frequency dependency of the amplifier cascade also remains unaffected by this. In the case of a partial frequency decoupling, the output stage loads the upstream amplifier cascade and distorts the frequency dependency of the output stage due to the frequency-dependent output impedance of the amplifier cascade. This distortion becomes stronger the greater the feedback resistance (i.e., the lower the feedback strength) of the amplifier cascade. Preferably, the decoupling is complete or nearly complete.

MOSFETs, bipolar transistors, and operational amplifiers are affordable, reliable, and technically simple components that are suitable for use as or else in the decoupler. Operational amplifiers with high input resistance and low inherent noise are preferred components for use in the decoupler, since they can provide a particularly strong decoupling up to complete or nearly complete decoupling. At the same time, they contribute only a little or not at all to the distortion of the signal amplified in the amplifier circuit according to the invention due to their low inherent noise. Operational amplifiers with high input resistance and low inherent noise, wherein the output of the operational amplifier is fed back directly to the inverting input, are particularly preferred, since they have the same advantageous properties as operational amplifiers with high input resistance and low inherent noise and additionally improve the decoupling even more.

The decoupler is preferably connected to the node K₄ and the input of the output stage. In particular, the decoupler can be directly or indirectly connected to the K₄ and the input of the output stage. In this context, a direct connection describes the connection “K₄—decoupler—input of output stage.” An indirect connection can have, for example, further electronic components between K₄ and the decoupler and/or the decoupler and the input of the output stage.

Providing the decoupler or else the non-inverting impedance converter provides a frequency decoupling of the amplifier cascade and the input of the output stage. This achieves a considerably flatter transfer function between the amplifier cascade and the output stage. As a result, the frequency dependency of the output of the amplifier circuit according to the invention is thereby lowered or else improved.

At the same time, the decoupler improves the amplification of the amplifier circuit according to the invention. In particular, the input signal of the amplifier circuit according to the invention can be amplified with a flat transfer function up to 360 kHz at, for example, an amplification of 50 MV/A.

In a preferred embodiment according to the first aspect of the invention, the amplifier circuit additionally comprises an intermediate load, wherein the intermediate load is connected to the output of the first amplifier and the input of the second amplifier of the amplifier cascade in the node K₃, wherein the intermediate load is configured to minimize natural vibrations of the amplifier circuit.

Within the meaning of the invention, the connection of the intermediate load to the output of the first amplifier of the amplifier cascade in the node K₃ means that the intermediate load can be connected directly or indirectly, for example to one or more intermediate electronic components, to the output of the first amplifier in the node K₃. A preferred electronic component in an indirect connection can be an ohmic resistor.

Within the meaning of the invention, the connection of the intermediate load to the input of the second amplifier of the amplifier cascade in the node K₃ means that the intermediate load can be connected directly or indirectly, for example by means of one or more intermediate electronic components, to the input of the second amplifier in the node K₃. A preferred electronic component in an indirect connection can be an ohmic resistor.

In a preferred embodiment according to the first aspect of the invention, the intermediate load is configured to minimize natural vibrations through a phase correction.

In a preferred embodiment according to the first aspect of the invention, the output of the first amplifier is connected to the node K₃ via a first ohmic resistor (R₁₇), wherein the node K₃ is connected to ground via a second ohmic resistor (R₁₅). The first resistor (R₁₇) and the second ohmic resistor (R₁₅) preferably form a voltage divider, at which a partial voltage can be tapped at the node K₃. The voltage divider advantageously restricts an excessive load, in particular of the upstream amplifier stage or else of the upstream operational amplifier.

In a preferred embodiment according to the first aspect of the invention, the intermediate load has at least one or more of the following combinations of components or consists thereof: inductor and/or capacitor connected in series to ground and at least one ohmic resistor, preferably the second ohmic resistor; inductor and/or capacitor connected in parallel to ground and at least one ohmic resistor. Particularly preferably, the intermediate load has an inductor or capacitor connected in series to ground and at least the second ohmic resistor or consists thereof. More preferably, the intermediate load has an inductor connected in series to ground and at least the second ohmic resistor or consists of an inductor connected in series to ground and at least the second ohmic resistor R₁₅.

In the context of the invention, an intermediate load describes any component or any combination of components that is/are suitable for minimizing the natural vibration of the amplifier circuit according to the invention. Preferably, the intermediate load is configured to introduce a phase correction that changes the frequency response such that the amplifier circuit according to the invention is more robust against natural vibrations. In the context of the invention, robustness against natural vibrations means that the feedback circuit, in particular the feedback network and/or the frequency response compensator, fulfills the Nyquist stability criterion. This means that the phase rotation of the feedback is so low that the desired negative feedback does not lead to unwanted positive feedback.

The aforementioned combinations of components are simple in structure and robust in use. Despite their simplicity, they also have the surprising effect of improving the advantageous properties of the amplifier circuit according to the invention.

Particularly preferably, the inductor of the intermediate load in the combination of components consisting of the inductor and at least one ohmic resistor, preferably the first and second ohmic resistors, has a value in the range of 1 μH to 20 μH, preferably in the range of 1 μH to 5 μH. Particularly preferably, the first and second ohmic resistors in the combination of components of the intermediate load consisting of the inductor and ohmic resistors has a value in the range of 10 ohms to 100 ohms, preferably in the range of 10 ohms to 20 ohms. Preferably, the first and second resistors are the same size. Surprisingly, these aforementioned values show particularly good results in minimizing unwanted natural vibrations.

Providing the intermediate load stabilizes the amplifier circuit according to the invention advantageously in the case of larger changes in the input capacitance of the capacitive current source. In particular, this enables the use of different capacitive current sources and/or pyroelectric sensors. This makes the circuit according to the invention usable more universally and without technically complex adaptations of the circuit.

In the second aspect of the invention, the object of the invention is achieved by the sensor system having the features of claim 20. The sensor system according to the invention according to claim 20 comprises a capacitive current source and an amplifier circuit according to one of claims 1 to 19.

The statements made in conjunction with the first aspect of the invention also apply in conjunction with the sensor system according to the second aspect of the invention. To avoid unnecessary redundancy, reference is made here to the statements made above and they will not be repeated here.

The capacitive current source can preferably have a component with a negative capacitance.

Within the meaning of the invention, a component with a negative capacitance is a component in which a reduction of the applied voltage results in an increase in the charge of the component. For this purpose, the component can have a material that has a negative capacitance. Initial experimental indications of such materials are given, for example, by M. Hoffmann, S. Slesazeck, and T. Mikolajick, “Progress and future prospects of negative capacitance electronics: A materials perspective,” APL Mater. 9, 020902 (2021) and A. K. Yadav, K. X. Nguyen, Z. Hong, et al. “Spatially resolved steady-state negative capacitance,” Nature 565, 468 (2019).

Examples of materials with a negative capacitance can be ferroelectric materials such as HfO₂ and lead zirconate titanate, or else heterostructures consisting of these ferroelectric and dielectric materials such as strontium titanate.

Preferably, the component with negative capacitance is connected, for example, to the capacitive current source at an output of the capacitive current source. Alternatively, the component with negative capacitance can be a part of the capacitive current source, preferably of the pyroelectric sensor. In both cases, the negative capacitance of the component can compensate for the normal, positive, capacitance of the capacitive current source, preferably of the pyroelectric sensor.

The use of such a component reduces the noise considerably and thus improves the signal-to-noise ratio when measuring the signal of the capacitive current source, preferably of the pyroelectric sensor.

In a preferred embodiment according to the second aspect of the invention, the capacitive current source is a pyroelectric sensor.

The pyroelectric sensor can have, for example, lithium tantalate (LiTaO₃) or triglycine sulfate (TGS).

Due to the special properties of the amplifier circuit according to the invention in the sensor system according to the invention, a particularly broadband and low-noise amplification of the signal of a pyroelectric sensor is possible.

In a preferred embodiment according to the second aspect of the invention, the pyroelectric sensor is designed in the shape of a plate and has a maximum thickness of 40 μm, preferably at most 10 μm.

A pyroelectric sensor typically has a crystal made of a pyroelectric material.

In the context of this invention, the thickness of the pyroelectric sensor describes the thickness of the pyroelectric material, i.e., the thickness or rather average thickness of the pyroelectric crystal.

The increase in temperature of the pyroelectric sensor, or rather of the crystal, is directly proportional to the absorption Aₜₕ of the radiation in the crystal and inversely proportional to its thermal capacity cₜₕ (optical-thermal conversion). The largest possible change in temperature is enabled by a suitable, broadband-absorbing coating of the crystal. In addition, a low thermal capacity can be achieved by a small crystal volume, or else by a low crystal thickness with a given sensor area. Cooling due, for example, to the thermal conduction of the crystal holder, counteracts the heating process of the sensor element. Poor thermal conduction here ensures a high temperature difference ΔT between the irradiated and non-irradiated crystal and therefore leads to a correspondingly high current signal. As the modulation frequency of the irradiated light ω increases, ΔT gets smaller and

$$Δ T ∝ \frac{{A}_{th}}{{c}_{th} ω}$$

applies. Therefore, a low heat capacity (a thin crystal) is advantageous for a thermal reaction of the sensor that is as fast as possible. A pyroelectric sensor with a low thickness thus ensures the fastest possible thermal reaction and an advantageous behavior of the pyroelectric sensor when the capacitance, which is increased due to the low thickness, of the sensor element does not exceed the useful limits of the input capacitance of the following amplifier circuit. Preferably, in the context of this invention, the thickness or rather the average thickness of the crystal is between 2 μm and 40 μm.

Another factor is the thermal-electric conversion: The change in temperature of the pyroelectric crystal generates a surface charge Q proportionally to the area A of the crystal and to the pyroelectric coefficient p, which describes the specific strength of the pyroelectric effect in a material: Q=pAΔT A temporal change in the temperature thus generates a temporally variable charge, meaning an electric current I. As a result, a pyroelectric sensor can respond only to radiation changes. In the stationary case, current no longer flows. At high frequencies, the pyroelectric current is constant independently of the frequency of the light excitation. The following applies here for the current:

$$I ∝ \frac{1}{{c}_{th}} ,$$

a low neat capacity (a thin crystal) is thus desirable at high frequencies even for a current signal that is as large as possible.

The low thickness of the pyroelectric sensor also results in an increase in the bandwidth up to the electronic bandwidth of the amplifier circuit according to the invention. In this case, both the optical-thermal conversion and the thermal-electric conversion is optimized due to the reduced heat capacity of the pyroelectric sensor.

The sensor system according to the invention according to one of claims 20 to 22 can preferably be used in and/or with an FTIR spectrometer (Fourier-transform infrared spectrometer). In particular, the sensor system according to the invention can be part of an FTIR spectrometer described above or be used therein.

It is hereby noted that one or more of the above-described preferred embodiments can be combined with each other, to the extent free from contradictions, and are also preferred embodiments.

In particular, one or more of the above-described preferred embodiments of the various aspects of the invention can also be combined with each other, to the extent free from contradictions, and are also preferred embodiments of the invention.

In the following, preferred embodiments of the invention are explained and described in more detail with reference to the accompanying drawings. The drawings show:

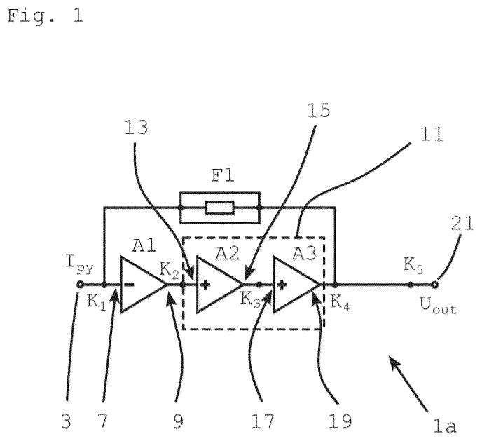

FIG. 1 a schematic representation of a circuit of a first embodiment of the amplifier circuit according to the invention,

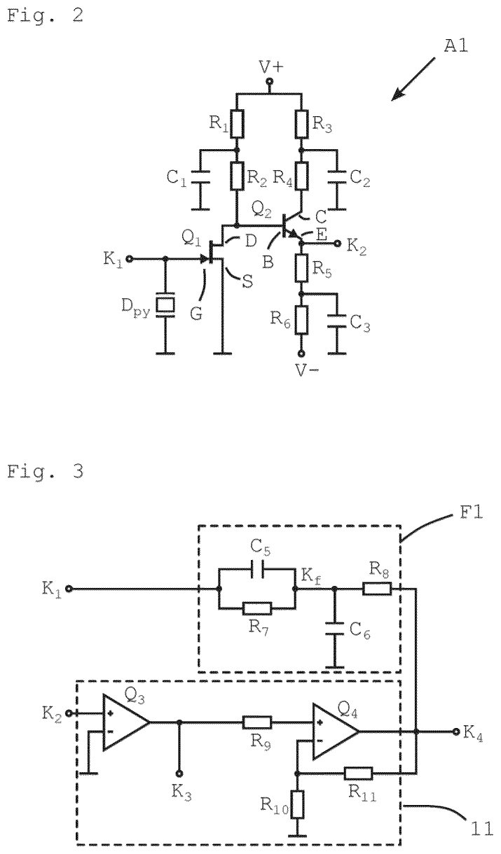

FIG. 2 a circuit diagram of an embodiment of an input stage,

FIG. 3 a circuit diagram of an embodiment of an amplifier cascade with a feedback network,

FIG. 4 a schematic representation of a circuit of a second embodiment of the amplifier circuit according to the invention,

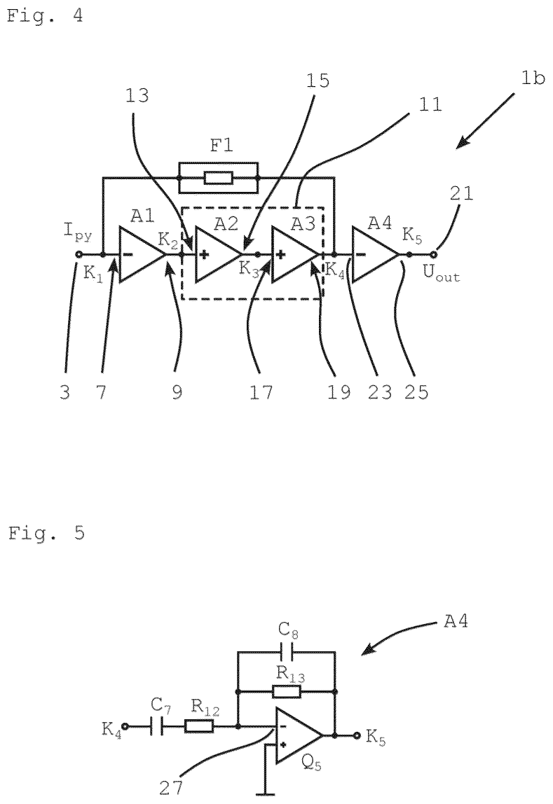

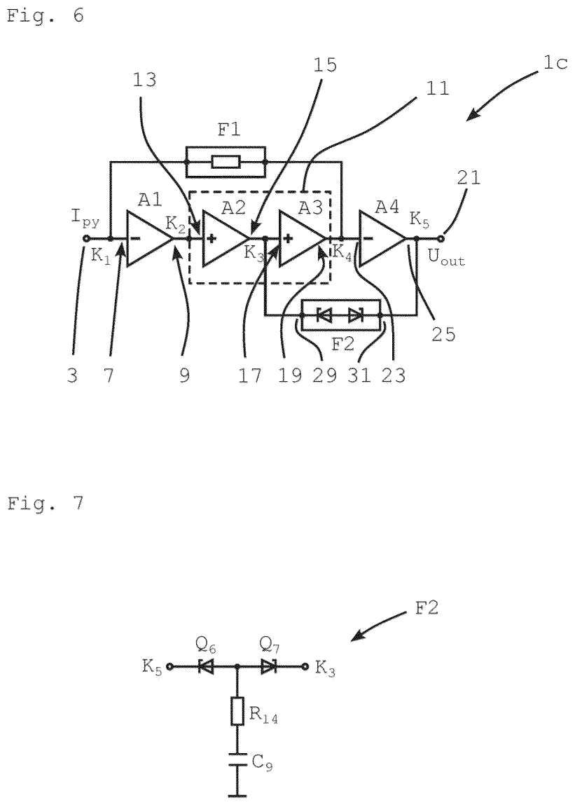

FIG. 5 a circuit diagram of an embodiment of an output stage,

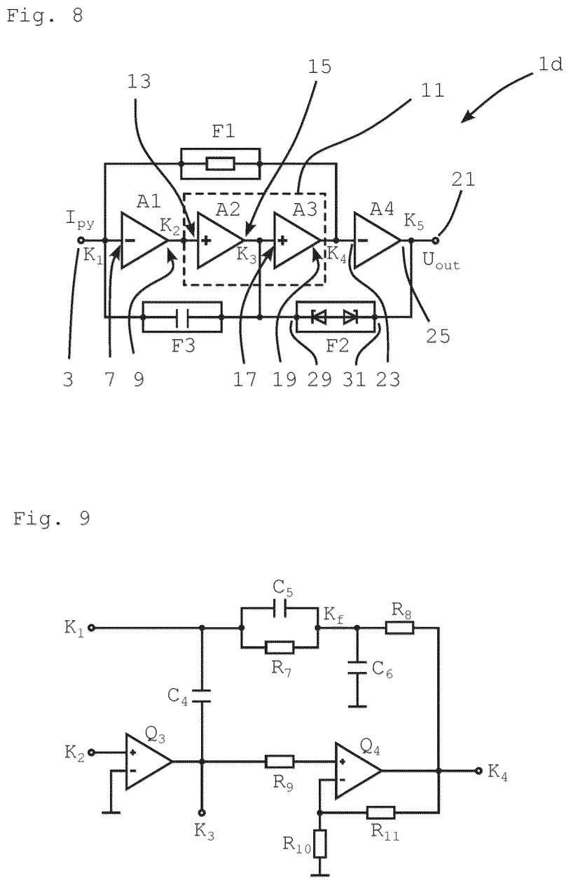

FIG. 6 a schematic representation of a circuit of a third embodiment of the amplifier circuit according to the invention,

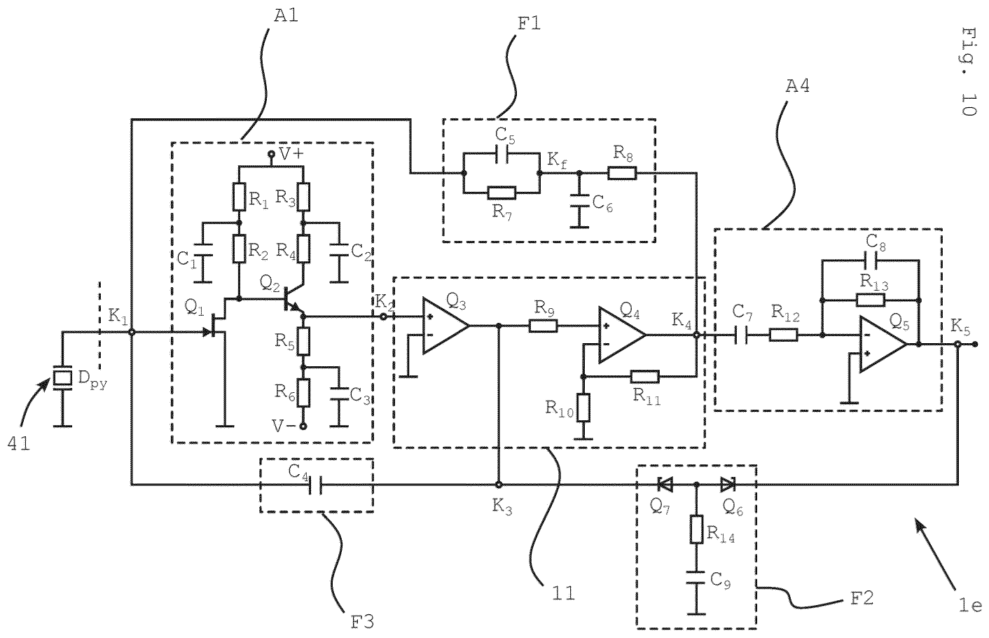

FIG. 7 a circuit diagram of an embodiment of an amplitude limiter,

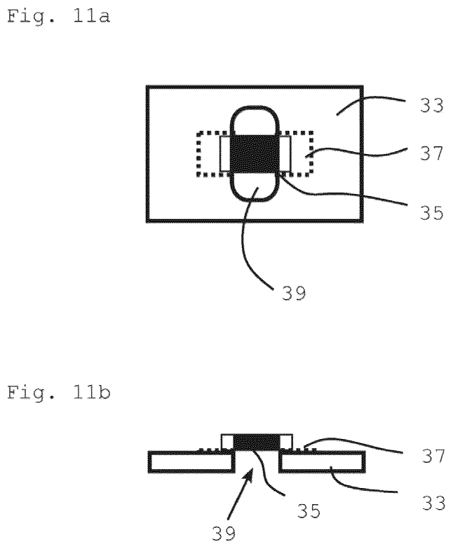

FIG. 8 a schematic representation of a circuit of a fourth embodiment of the amplifier circuit according to the invention,

FIG. 9 a circuit diagram of an embodiment of an amplifier cascade with a feedback network and frequency compensator,

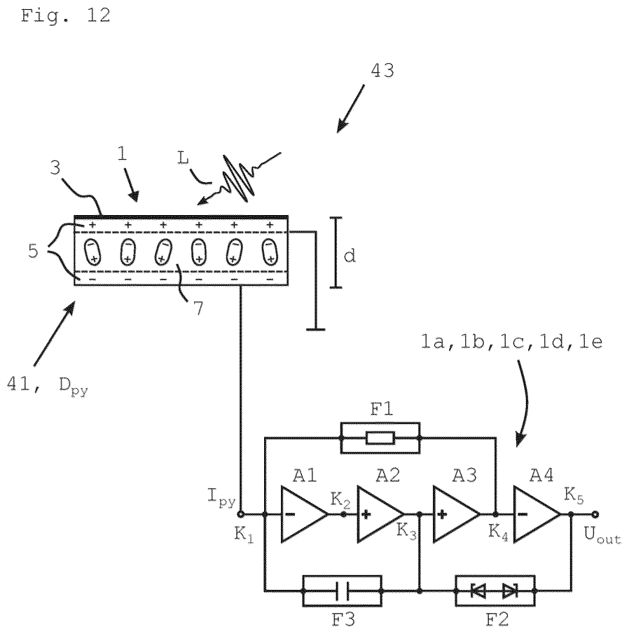

FIG. 10 a circuit diagram of a fifth embodiment of the amplifier circuit according to the invention,

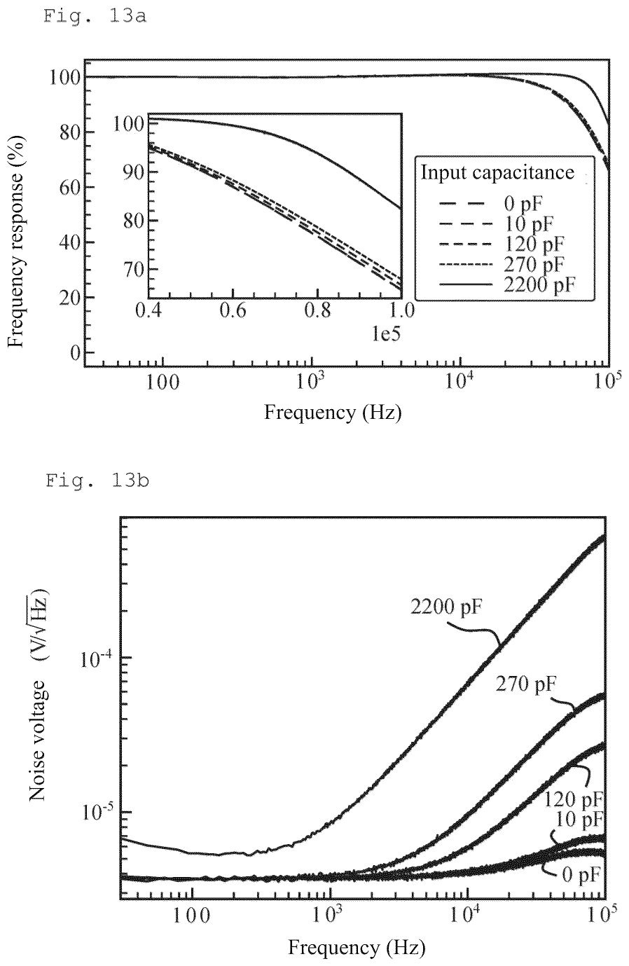

FIG. 11 a,b a representation of a component on a circuit board with a region removed,

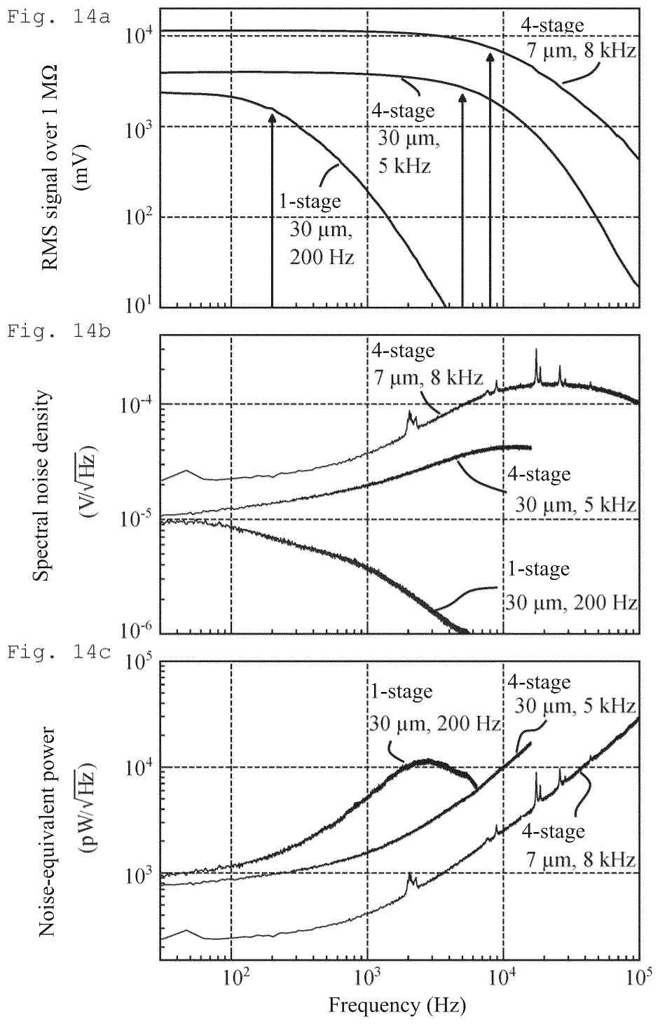

FIG. 12 an embodiment of a sensor system according to the invention,

FIG. 13 a,b a representation of measurement results of the performance of the amplifier circuit according to the invention,

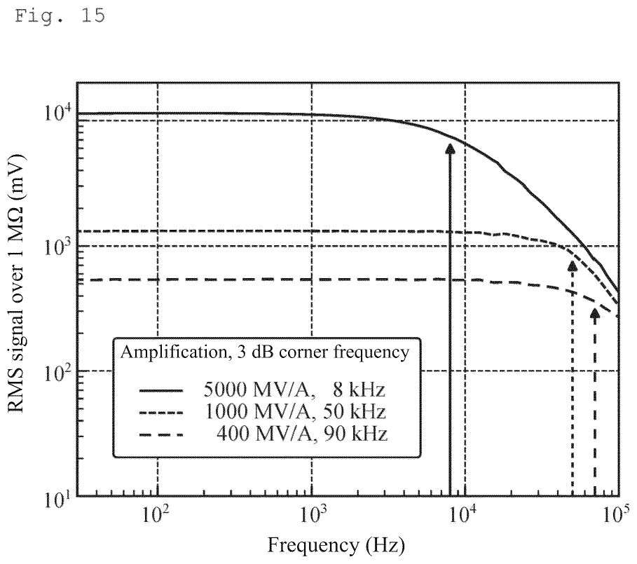

FIG. 14 a,b,c a representation of measurement results of the performance of the sensor system according to the invention,

FIG. 15 a representation of measurement results of the transfer behavior at different amplifications,

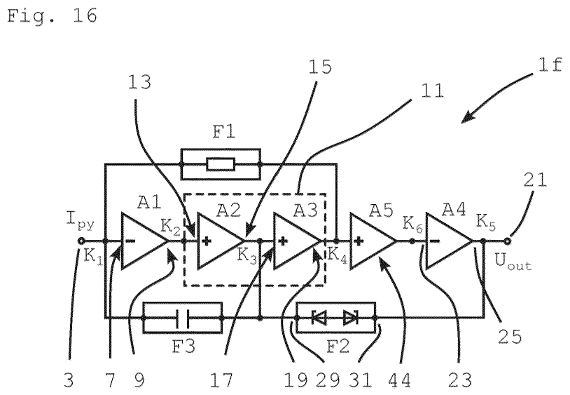

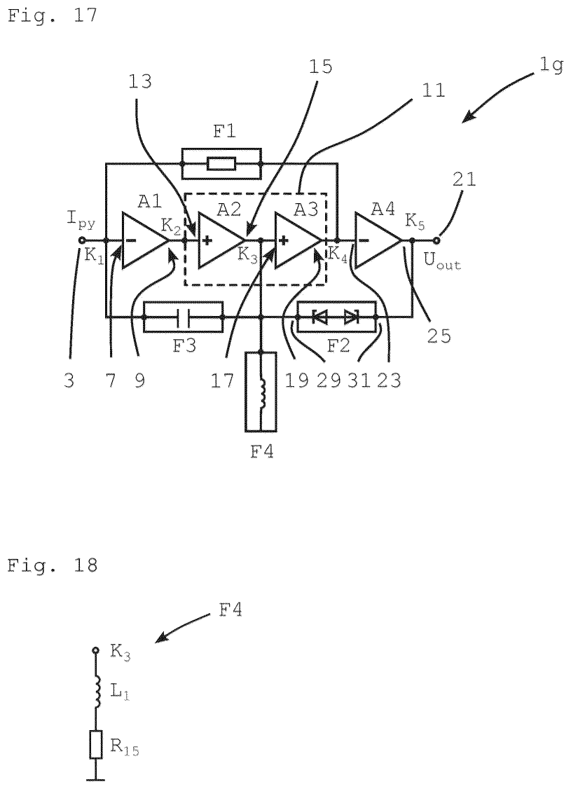

FIG. 16 a schematic representation of a circuit of a sixth embodiment of the amplifier circuit according to the invention,

FIG. 17 a schematic representation of a circuit of a seventh embodiment of the amplifier circuit according to the invention,

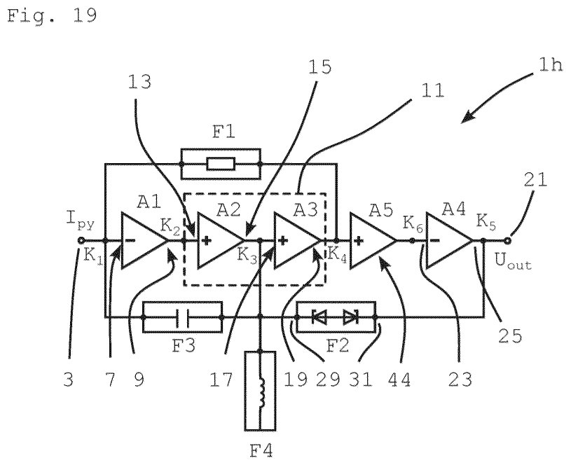

FIG. 18 a circuit diagram of an embodiment of an intermediate load,

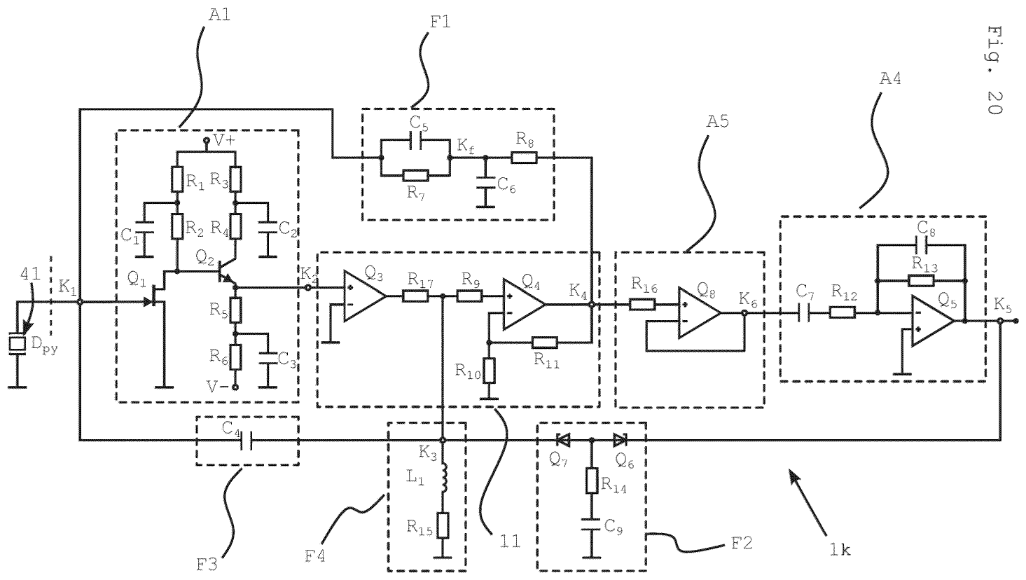

FIG. 19 a schematic representation of a circuit of an eighth embodiment of the amplifier circuit according to the invention,

FIG. 20 a circuit diagram of a ninth embodiment of the amplifier circuit according to the invention, and

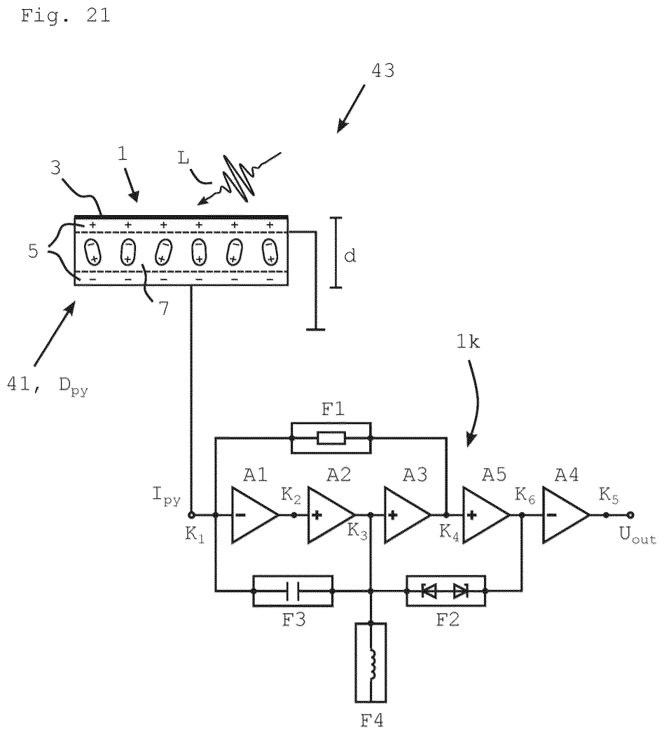

FIG. 21 a second embodiment of a sensor system according to the invention.

FIG. 1 shows a schematic representation of a circuit of a first embodiment of the amplifier circuit 1a according to the invention. The amplifier circuit 1a is an amplifier circuit for broadband and low-noise amplification of a capacitive current source, preferably of a pyroelectric sensor. The amplifier circuit 1a comprises

a signal input 3, which can be connected to the capacitive current source in a node K₁; an input stage A1, wherein the input stage A1 is connected to the node K₁ at an input 7 of the input stage A1 and has a node K₂ at the output 9 of the input stage A1, wherein the input stage A1 is configured to amplify an input voltage at least 3-fold, wherein the input stage A1 is configured to provide a high-ohm input resistance at the input 7 of the input stage A1, wherein the input stage A1 is configured to provide a stable and load-independent voltage at the output 9 of the input stage A1; an amplifier cascade 11, wherein the amplifier cascade 11 has at least one first amplifier A2 and a second amplifier A3, each with an input 13 and 17, respectively, and an output 15 and 19, respectively, wherein the output 15 of the first amplifier A2 is connected to the input 17 of the second amplifier A3 in a node K₃, wherein the input 13 of the first amplifier A2 is connected to the node K₂, wherein the output 19 of the second amplifier A3 is connected to a node K₄, wherein the amplifier cascade 11 is configured to generate a high signal amplification with a low phase rotation over a wide frequency range; a feedback network F1, wherein the feedback network F1 is connected to the input 7 of the input stage A1 in the node K₁ and to the output 19 of the second amplifier A3 in the node K₄, wherein the feedback network F1 is configured to provide a high-ohm feedback resistor with a parasitic capacitance of less than 0.5 pF, wherein the feedback network F1 is configured to provide a negative feedback to an assembly comprising the input stage A1 and the amplifier cascade 11; and a signal output 21, which is connected to a node K₅, wherein the node K₅ is connected to the node K₄ or corresponds to the node K₄.

FIG. 2 shows an example of an input stage A1. The input stage A1 has a junction field-effect transistor Q₁ and a bipolar transistor Q₂. The junction field-effect transistor Q₁ has three connections: source S, gate G, and drain D. The bipolar transistor Q₂ has three connections: collector C, base B, and emitter E. The drain connection of the junction field-effect transistor Q₁ is connected to the base connection B of the bipolar transistor Q₂. The junction field-effect transistor Q₁ is wired as a source circuit. The bipolar transistor Q₂ is wired as an emitter follower.

The input stage A1 can additionally or alternatively have a component with a negative capacitance.

FIG. 3 shows an example of an amplifier cascade 11 with an example of a feedback network F1. The first and second amplifiers A2, A3 of the amplifier cascade 11 are each an operational amplifier Q₃, Q₄. The first operational amplifier Q₃ can have a voltage amplification of more than 10⁴. The second operational amplifier Q₄ can have a voltage amplification of at most 10³.

The feedback network F1 has a high-ohm feedback resistor R₇ with a parallel capacitor C₅. Additionally, the feedback network F1 has a low-pass connected in series. The low-pass has a resistor R₈ and a capacitor C₆ to ground. The low-pass is connected to the feedback resistor R₇ and the parallel capacitor C₅ in the node K_{f}.

FIG. 4 shows a schematic representation of a circuit of a second embodiment of the amplifier circuit 1b according to the invention. The circuit shown in FIG. 4 is an expansion of the circuit from FIG. 1 and thus has all the elements from FIG. 1 as well as their functions. FIG. 4 additionally shows an output stage A4. The output stage A4 is connected to the node K₄ at an input 23 of the output stage A4 and is connected to the signal output 21 in the node K₅ at an output 25 of the output stage A4.

The output stage A4 is configured to amplify a voltage at the input of the output stage by up to 20-fold. The output stage A4 is also configured to filter DC voltage disturbances at the input 23 of the output stage A4 and to adapt a signal level at the output 25 of the output stage A4 to K₅.

FIG. 5 shows a circuit diagram of an example of an output stage A4. The output stage A4 comprises an inverting bandpass amplifier Q₅. An inverting input 27 of the bandpass amplifier A4 is AC-coupled by means of a capacitor C₇ connected in series.

FIG. 6 shows a schematic representation of a circuit of a third embodiment of the amplifier circuit 1c according to the invention. The circuit shown in FIG. 6 is an expansion of the circuit from FIGS. 1 and 4 and thus has all the elements from FIGS. 1 and 4 as well as their functions.

FIG. 6 additionally shows an amplitude limiter F2, which is comprised in the amplifier circuit 1c. The amplitude limiter F2 is connected to the node K₄ or K₅ at an input 31 of the amplitude limiter F2 and is connected to the node K₃ at an output 29 of the amplitude limiter F2. The amplitude limiter F2 is configured to limit the amplitude of the output signal at the signal output 21 when a threshold is exceeded at the node K₄ or node K₅.

FIG. 7 shows a circuit diagram of an example of an amplitude limiter F2. The amplitude limiter F2 has two Z-diodes Q₆, Q₇ connected in series with opposing polarity.

FIG. 8 shows a schematic representation of a circuit of a fourth embodiment of the amplifier circuit 1d according to the invention. The circuit shown in FIG. 8 is an expansion of the circuit from FIGS. 1, 4, and 6 and thus has all the elements from FIGS. 1, 4, and 6 as well as their functions.

FIG. 8 additionally shows a frequency response compensator F3, which is comprised in the amplifier circuit 1d. The frequency response compensator F3 is connected to the node K₃ and the node K₁ and is configured to decrease a vibration tendency of the amplifier cascade 11.

FIG. 16 shows a schematic representation of a circuit of a sixth embodiment of the amplifier circuit 1f according to the invention. The amplifier circuit 1f shown in FIG. 16 is an expansion of the circuit from FIG. 8. FIG. 16 shows the amplifier circuit 1d shown in FIG. 8 with an additional decoupler A5. The decoupler A5 is connected to the node K₄ and the input 23 of the output stage A4. The decoupler is configured to decouple an output of the amplifier cascade 11 from the output stage A4.

Preferably, the decoupler A5 has or is a non-inverting impedance converter Q₈. Alternatively, however, the decoupler A5 can also be or have a combination of two inverting impedance converters.

FIG. 17 shows a schematic representation of a circuit of a seventh embodiment of the amplifier circuit 1g according to the invention. The amplifier circuit 1g shown in FIG. 17 is an expansion of the circuit from FIG. 8. FIG. 17 shows the amplifier circuit 1d shown in FIG. 8 with an additional intermediate load F4. The intermediate load F4 is connected to the output 15 of the first amplifier A2 and the input 17 of the second amplifier A3 of the amplifier cascade 11 in the node K₃. The intermediate load F4 is configured to minimize natural vibrations of the amplifier circuit 1g. Preferably, the intermediate load F4 is configured to minimize the natural vibrations of the amplifier circuit 1g through a phase correction.

FIG. 18 shows an example of an implementation of an intermediate load F4. The intermediate load F4 is shown by way of example as an inductor L₁ connected in series to ground and an ohmic resistor R₁₅. However, alternative embodiments of the intermediate load F4 are also conceivable.

FIG. 19 shows a schematic representation of a circuit of an eighth embodiment of the amplifier circuit 1h according to the invention. The amplifier circuit 1h shown in FIG. 19 is an expansion of the circuit from FIG. 16 with an additional intermediate load F4.

FIG. 9 shows the example shown in FIG. 3 of an amplifier cascade 11 with an additional example of a frequency response compensator F3. The frequency response compensator F3 has a capacitor, for example a capacitor C₄, connected in series. The capacitor C₄ is connected to the nodes K₁ and K₃. The frequency response compensator F3 is configured to decrease a vibration tendency of the amplifier cascade 11.

FIG. 10 shows a circuit diagram of a fifth embodiment of the amplifier circuit 1e according to the invention. The amplifier circuit in this case combines the component groups shown in FIGS. 2, 3, 5, 7, and 9 to form an overall amplifier circuit 1e according to the invention. Additionally, FIG. 10 shows a capacitive current source 41, which is designed as a pyroelectric sensor D_{py} and which can be connected and is connected to the amplifier circuit 1e in the node K₁. The amplifier circuit 1e is particularly preferred.

FIG. 20 shows a circuit diagram of a ninth embodiment of the amplifier circuit 1k according to the invention. The amplifier circuit 1k in this case combines the amplifier circuit shown in FIG. 10 with the intermediate load shown in FIG. 18 and the decoupler A5 shown in FIG. 16 in the form of another operational amplifier Q₈. The output of the operational amplifier Q₈ is directly fed back to its inverting input.

The amplifier circuit 1k is particularly preferred.

The output of the first operational amplifier Q₃ is connected to the node K₃ via a first resistor R₁₇, wherein the node K₃ is connected to the non-inverting input of the second operational amplifier Q₄ via an ohmic resistor R₉.

The intermediate load F4 is shown by way of example as an inductor L₁ connected in series to ground and the second ohmic resistor R₁₅. However, alternative embodiments of the intermediate load F4 are also conceivable. The ohmic resistor R₁₇ and the ohmic resistor R₁₅ form a voltage divider. The voltage divider advantageously restricts an excessive load of the upstream amplifier stage or else of the upstream operational amplifier.

Preferably, the resistors R₁₅ and R₁₇ are the same size. Surprisingly, these aforementioned values show particularly good results in minimizing unwanted natural vibrations.

The first to fifth embodiments of the amplifier circuit 1a, 1b, 1c, 1d, 1e can preferably be used for measuring a current signal of a capacitive current source, preferably of a pyroelectric sensor. Any embodiment, in particular also the sixth to ninth embodiments of the amplifier circuit 1a, 1b, 1c, 1d, 1e, 1f, 1g, 1h, 1k according to the invention (put simply: amplifier circuit 1) can preferably be used for measuring a current signal of a capacitive current source, preferably of a pyroelectric sensor.

The amplifier circuit 1a, 1b, 1c, 1d, 1e, 1f, 1g, 1h, 1k can preferably be used for measuring a current signal of a capacitive current source, preferably of a pyroelectric sensor, in an infrared spectrometer, preferably an FTIR spectrometer (Fourier-transform infrared spectrometer).

FIG. 11 shows a portion of a circuit board 33, which can also be called a printed circuit board. The amplifier circuit 1a, 1b, 1c, 1d, 1e, 1f, 1g, 1h, 1k (referred to in the following simply as amplifier circuit 1 for better readability) or at least a part of the amplifier circuit 1 is mounted on a circuit board 33. By way of example, FIG. 11 shows an electronic component 35 of the amplifier circuit 1 on the circuit board 33. The electronic component 35 is soldered to the circuit board 33 with solder pads 37. A region 39 of the circuit board 33 below the at least one electronic component 35 outside of the solder pads 37 is removed.

The region 39 of the circuit board 33 can preferably be removed below an electronic component 35 or multiple components of the feedback network F1 or below the entire feedback network F1.

Alternatively or additionally, the region 39 of the circuit board 33 below an electronic component or multiple components of the input stage A1 can preferably be removed. Particularly preferably, the region 39 below the field-effect transistor Q₁ and/or the region 39 below the bipolar transistor Q₂ is removed.

FIG. 12 shows an embodiment of a sensor system 43 according to the invention comprising a capacitive current source 41 and an amplifier circuit 1. Preferably, the capacitive current source of the sensor system 43 is a pyroelectric sensor D_{py}.

FIG. 21 shows another embodiment of a sensor system 43 according to the invention comprising a capacitive current source 41 and an amplifier circuit 1k. Preferably, the capacitive current source of the sensor system 43 is a pyroelectric sensor D_{py}.

The pyroelectric sensor D_{py} can preferably be designed in the shape of a plate and have a maximum thickness d of 40 μm, preferably at most 10 μm.

The sensor system 43 according to the invention can preferably be used in and/or with an FTIR spectrometer (Fourier-transform infrared spectrometer).

FIG. 13 a, b shows a representation of measurement results of the performance of the amplifier circuit according to the invention. FIG. 14 a, b, c each show a representation of measurement results of the performance of the sensor system according to the invention, and FIG. 15 shows a representation of measurement results of the transfer behavior at different amplifications.

FIG. 13 shows measurement data regarding the transfer of the four-stage amplifier circuit 1 according to the invention and demonstrates the performance and advantages of the invention. Despite a 40-fold higher amplification of 400 MV/A compared to a typical TIA, in which the amplification is typically only 10 MV/A, the amplifier circuit 1 according to the invention shows a flat transfer up to a 3 dB cutoff frequency of 90 kHz. The amplifier circuit 1 thus achieves the same bandwidth as the TIA known in the prior art with a lower amplification of 10 MV/A. In other words, the amplifier circuit 1 achieves a considerably greater amplification at a comparable bandwidth compared to the prior art. In addition, the presented circuit is robust against a change in the input capacitance, in particular on account of the capacitive current source 41, for example, a pyroelectric sensor D_{py}. The transfer functions of 0 pF-270 pF are almost identical. Even at the large input capacitance of 2.2 nF, there is still not yet an excessive increase in the frequency response as with TIAs known in the prior art.

The noise voltage of the amplifier circuit according to the invention is shown in FIG. 13b and is only slightly higher at low frequencies than the minimally possible Johnson-Nyquist noise of a 400 MΩ feedback resistor of

$$\sqrt{4 {k}_{B} \cdot 300 K \cdot 400 MΩ} = 2 , 6 \cdot {10}^{- 6} \frac{V}{\sqrt{Hz}} .$$

At higher frequencies starting at 10⁴ Hz, the noise depends on the input capacitance: the higher this is, the more likely and strongly the noise increases. This is due, on the one hand, to a reduction in the input impedance of the capacitive current source 41, which leads to a greater amplification of the input voltage noise. On the other hand, the dielectric loss of the sensor, which increases with the frequency, effectively reduces its resistance R_{py}. This generates a further contribution to the noise.

Preferably, the capacitance of the pyroelectric sensor D_{py} can be compensated for by a passive structural element with a negative capacitance (see above). According to FIG. 13b, a combination of a component with a negative capacitance with a capacitive current source 41, preferably a pyroelectric sensor D_{py} with a usual positive capacitance, promises a further considerable reduction in noise and thus also a considerably improved signal-to-noise ratio.

The performance of the amplifier circuit 1 according to the invention has been tested in conjunction with a pyroelectric sensor D_{py}, i.e., as a sensor system according to the invention, in an optical assembly (see FIG. 14a to c). For this purpose, the sensitivity at an amplification of 5 GV/A was measured over a frequency range up to 100 kHz with a pulsed diode laser with a power of 145 μW and compared to a single-stage TIA known in the prior art with a pyroelectric sensor D_{py} with the same amplification. At the same thickness of the pyroelectric sensor D_{py} of 30 μm, the bandwidth of the four-stage amplifier circuit 1 according to the invention (see FIG. 13a to c) of 5 kHz is considerably greater than the 200 Hz bandwidth of the single-stage TIA (see FIG. 13a to c). In this case, the cutoff frequency of 5 kHz corresponds to the thermal time constant of the pyroelectric sensor D_{py} with a thickness of 30 μm. At this advantageous high amplification, the amplifier circuit 1 according to the invention has a very high electronic cutoff frequency of 8 kHz.

Considerably more signal and a further increase in the bandwidth up to the electronic bandwidth of the amplifier circuit 1 according to the invention is obtained by reducing the thickness of the pyroelectric sensor D_{py}. In this case, both the optical-thermal conversion and the thermal-electric conversion is optimized due to the reduced heat capacity of the pyroelectric sensor. The corresponding curves in FIG. 14a to c show this effect using a 7 μm thick pyroelectric sensor D_{py}. Compared to the thicker pyroelectric sensor D_{py}, the signal is more than doubled with the same amplifier circuit according to the invention and the bandwidth increases up to the electronic bandwidth of 8 kHz.

As already in FIG. 13b, the noise proportion in FIG. 14a to c at low frequencies is primarily Johnson-Nyquist noise of the feedback resistor. The noise of the sensor system with the four-stage amplifier 1 according to the invention increases as expected as the frequency increases. The absolute value of the noise depends significantly on the capacitance C_{py} of the pyroelectric sensor D_{py} and its loss factor tan (8). Both variables are larger with the thinner 7 μm pyroelectric sensor (C_{py}≈250 pF) than with the 30 μm thick pyroelectric sensor (C_{py}≈120 pF). For the selected thicknesses of the pyroelectric sensor, this effect is overcompensated by the signal increase of the thinner pyroelectric sensor, such that, despite this, it has a considerably lower noise-equivalent power (NEP) or else a better signal-to-noise ratio (cf. FIG. 14c). Overall, the performance of both sensor systems with the four-stage amplifier circuit 1 according to the invention is considerably better than in sensor systems known in the prior art over the entire frequency range but especially at frequencies higher than 200 Hz. The bandwidth is greater at the same amplification and measurements above 1 kHz can be realized without any problems. Thanks to the insensitivity of the four-stage amplifier circuit 1 according to the invention to larger input capacitances, thinner pyroelectric crystals can be used in the pyroelectric sensor with higher capacitance and greater signal, without this reducing the bandwidth or the transfer forming an excessive increase.

With the four-stage amplifier circuit 1 according to the invention, the bandwidth of the 7 μm thick pyroelectric sensor can be increased to well over 8 kHz with a flat transfer function when the amplification is reduced (see FIG. 15). At an amplification of 400 MV/A, the cutoff frequency of the detector of 70 kHz is no longer restricted by the electronic bandwidth (90 kHz).

1. An amplifier circuit (1) for broadband and low-noise amplification of a capacitive current source, preferably of a pyroelectric sensor, comprising
a signal input (3), which can be connected to the capacitive current source in a node K₁, an input stage (A1),
wherein the input stage (A1) is connected to the node K₁ at an input (7) of the input stage (A1) and has a node K₂ at the output (9) of the input stage (A1),
wherein the input stage (A1) is configured to amplify an input voltage at least 3-fold,
wherein the input stage (A1) is configured to provide a high-ohm input resistance at the input of the input stage (A1),
wherein the input stage (A1) is configured to provide a stable and load-independent voltage at the output of the input stage (A1),
an amplifier cascade,
wherein the amplifier cascade (11) has at least one first and one second amplifier (A2, A3), each with an input (13, 17) and an output (15, 19),
wherein the output (15) of the first amplifier (A2) is connected to the input (17) of the second amplifier (A3) in a node K₃,
wherein the input (13) of the first amplifier (A2) is connected to the node K₂,
wherein the output (19) of the second amplifier (A3) is connected to a node K₄,
wherein the amplifier cascade (11) is configured to generate a high signal amplification with a low phase rotation over a wide frequency range,
a feedback network (F1),
wherein the feedback network (F1) is connected to the input (7) of the input stage (A1) in the node K₁ and the output (19) of the second amplifier (A3) in the node K₄,
wherein the feedback network (F1) is configured to provide a high-ohm feedback resistor with a parasitic capacitance of less than 0.5 pF,
wherein the feedback network (F1) is configured to provide negative feedback to an assembly comprising the input stage (A1) and the amplifier cascade (11), and
a signal output (21), which is connected to a node K₅, wherein the node K₅ is connected to the node K₄ or corresponds to the node K₄.

2. The amplifier circuit (1) according to claim 1, wherein the input stage (A1) has a junction field-effect transistor (Q₁) and a bipolar transistor (Q₂),
wherein a drain connection of the junction field-effect transistor (Q₁) is connected to a base connection of the bipolar transistor,
wherein the junction field-effect transistor (Q₁) is wired as a source circuit,
wherein the bipolar transistor (Q₂) is wired as an emitter follower, wherein the first and second amplifiers (A2, A3) of the amplifier cascade (11) are an operational amplifier (Q₃, Q₄),
wherein the first operational amplifier (Q₃) has a voltage amplification of more than 10⁴,
wherein the second operational amplifier (Q₄) has a voltage amplification of at most 10³,
wherein the feedback network (F1) has a high-ohm feedback resistor with a parallel capacitor,
wherein the feedback network (F1) has a low-pass connected in series.

3. The amplifier circuit (1) according to claim 1, wherein the amplifier circuit additionally has an output stage (A4),
wherein the output stage (A4) is connected to the node K₄ at an input of the output stage (A4) and is connected to the signal output in the node K₅ at an output of the output stage (A4),
wherein the output stage (A4) is configured to amplify a voltage at the input of the output stage by up to 20-fold,
wherein the output stage (A4) is configured to filter DC voltage disturbances at the input of the output stage and to adapt a signal level at the output of the output stage (A4) to K₅.

4. The amplifier circuit (1) according to claim 3, wherein the output stage (A4) comprises an inverting bandpass amplifier, wherein an input of the bandpass amplifier is AC-coupled.

5. The amplifier circuit (1) according to claim 1, wherein the amplifier circuit additionally comprises an amplitude limiter (F2),
wherein the amplitude limiter (F2) is connected to the node K₄ or K₅ at an input of the amplitude limiter (F2) and is connected to the node K₃ at an output of the amplitude limiter (F2),
wherein the amplitude limiter (F2) is configured to limit the amplitude of the output signal at the signal output when a threshold is exceeded at the node K₄ or node K₅.

6. The amplifier circuit (1) according to claim 5, wherein the amplitude limiter (F2) has two Z-diodes (Q₆, Q₇) connected in series with opposing polarity.

7. The amplifier circuit (1) according to claim 1, wherein the amplifier circuit (1) comprises a frequency response compensator (F3),
wherein the frequency response compensator (F3) is connected to the node K₃ and the node K₁,
wherein the frequency response compensator (F3) is configured to decrease a vibration tendency of the amplifier cascade (11).

8. The amplifier circuit (1) according to claim 7, wherein the frequency response compensator (F3) has a negative feedback via a capacitor.

9. The amplifier circuit (1) according to claim 1, wherein the input stage (A1) has a component with a negative capacitance.

10. The amplifier circuit (1) according to claim 1,
wherein the amplifier circuit (1) or at least a part of the amplifier circuit (1) is mounted on a circuit board (33),
wherein at least one electronic component of the amplifier circuit (1) is soldered to the circuit board (33) with solder pads (37) on the circuit board (33),
wherein a region (39) of the circuit board (33) below the at least one electronic component outside of the solder pads is removed.

11. The amplifier circuit (1) according to claim 10, wherein the at least one electronic component is or else are one electronic component or multiple components of the feedback network (F1) or is the entire feedback network (F1).

12. The amplifier circuit (1) according to claim 10, wherein the at least one electronic component is or else are one electronic component or multiple components of the input stage (A1), preferably the junction field-effect transistor (Q₁) and/or the bipolar transistor (Q₂).

13. The amplifier circuit (1) according to claim 3,
wherein the amplifier circuit (1) additionally comprises a decoupler (A5),
wherein the decoupler (A5) is connected to the node K₄ and the input (23) of the output stage (A4),
wherein the decoupler (A5) is configured to decouple an output of the amplifier cascade (11) from the output stage (A4).

14. The amplifier circuit (1) according to claim 13,
wherein the decoupler (A5) has an impedance converter, preferably a non-inverting impedance converter or a combination of two inverting impedance converters, or
wherein the decoupler (A5) is an impedance converter, preferably a non-inverting impedance converter or a combination of two inverting impedance converters.

15. The amplifier circuit (1) according to claim 14,
wherein the impedance converter has at least one or more of the following components or is one of the following components: MOSFET, bipolar transistor, operational amplifier (Q₈), operational amplifier (Q₈) with high input resistance and low inherent noise, operational amplifier (Q₈) with high input resistance and low inherent noise, wherein the output of the operational amplifier (Q₈) is directly or indirectly fed back to its inverting input.

16. The amplifier circuit (1) according to claim 1,
wherein the amplifier circuit (1) additionally comprises an intermediate load (F4),
wherein the intermediate load (F4) is connected to the output (15) of the first amplifier (A2) and the input (17) of the second amplifier (A3) of the amplifier cascade (11) in the node K₃,
wherein the intermediate load (F4) is configured to minimize natural vibrations of the amplifier circuit (1).

17. The amplifier circuit (1) according to claim 16,
wherein the intermediate load (F4) is configured to minimize natural vibrations through a phase correction.

18. The amplifier circuit (1) according to claim 16,
wherein the output (15) of the first amplifier (A2) is connected to the node K₃ via a first ohmic resistor (R₁₇),
wherein the node K₃ is connected to ground via a second ohmic resistor (R₁₅).

19. The amplifier circuit (1) according to claim 18,
wherein the intermediate load has at least one or more of the following combinations of components or consists thereof: inductor (L₁) and/or capacitor connected in series to ground and at least one ohmic resistor, preferably the second ohmic resistor (R₁₅); inductor and/or capacitor connected in parallel to ground and at least one ohmic resistor (R₁₅).

20. A sensor system (43) comprising a capacitive current source and an amplifier circuit (1) according to claim 1.

21. The sensor system (43) according to claim 20, wherein the capacitive current source is a pyroelectric sensor (D_{py}).

22. The sensor system (43) according to claim 20, wherein the pyroelectric sensor (D_{py}) is designed in the shape of a plate and has a maximum thickness of 40 μm, preferably at most 10 μm.
